(19) United States
(12) Patent Application Publication
(10) Pub. No.: US 2016/0077442 A1
(43) Pub. Date: Mar. 17, 2016

(54) OPTICAL COMPONENT

(71) Applicant: Carl Zeiss SMT GmbH, Oberkochen (DE)

(72) Inventors: Adrian Staicu, Langenau (DE); Johannes Eisenmenger, Ulm (DE)

(21) Appl. No.: 14/941,498

(22) Filed: Nov. 13, 2015

Related U.S. Application Data
(63) Continuation of application No. PCT/EP2014/056532, filed on Apr. 1, 2014.

(30) Foreign Application Priority Data
May 22, 2013 (DE) 102013209442.6
Sep. 18, 2013 (DE) 102013218748.3

(51) Int. Cl. G03F 7/20; G02B 26/08; G02B 5/09; G02B 26/02

(52) U.S. Cl. CPC G03F 7/7015; G02B 26/02; G02B 26/0833; G02B 5/09

(57) ABSTRACT

An optical component includes a mechanism for reducing a radiation-induced influence on the displacement of an optical device.

### CROSS-REFERENCE TO RELATED APPLICATION

The present application is a continuation of, and claims benefit under 35 USC 120 to, international application PCT/EP2014/056532, filed Apr. 1, 2014, which claims benefit under 35 USC 119 of German Application No. 10 2013 209 442.6, filed May 22, 2013 and German Application No. 10 2013 218 748.3, filed Sep. 18, 2013. The contents these applications are hereby incorporated by reference herein.

### FIELD

The disclosure relates to an optical component. The disclosure furthermore relates to a method for positioning at least one optical device. Moreover, the disclosure relates to an illumination optical unit and an illumination system for a projection exposure apparatus and a projection exposure apparatus including such an illumination optical unit. In addition, the disclosure relates to a method for producing a micro- or nanostructured component.

### BACKGROUND

WO 2009/100 856 A1, for example, discloses a facet mirror for a projection exposure apparatus, the facet mirror having a multiplicity of individually displaceable individual mirrors. In order to ensure the optical quality of a projection exposure apparatus, a very precise positioning of the displaceable individual mirrors is involved.

### SUMMARY

The disclosure seeks to provide an improved optical component.

The disclosure involves providing the optical component with at least one mechanism for reducing a radiation-induced influence on the positioning of at least one optical device. The optical component includes, in particular, at least one mechanism for reducing the influences of the electrical charges liberated by the illumination radiation.

In particular, the stability of the at least one optical device is improved as a result. This leads to a more precise positioning of the at least one optical device.

According to the disclosure it has been recognized that high-energy photons can lead to a charge transfer to an optical device or away from an optical device, wherein the charge transfer, in the case of a device displaceable in an electromechanically actuable manner, can lead to a mechanical excitation thereof. In other words, the optical device can be mechanically excited and/or disturbed by the impingement of illumination radiation.

The displaceable optical device can be in particular a mirror, in particular a micromirror, that is to say a mirror having a side length of less than 1 mm. The mirror or micromirror can be in particular part of a multimirror arrangement (Multi Mirror Array, MMA). The MMA can include more than 1000, in particular more than 10 000, in particular more than 100 000, mirrors of this type. In particular, mirrors for reflecting VUV or EUV radiation can be involved.

The optical component can be in particular a facet mirror, in particular a field facet mirror, of an illumination optical unit for a projection exposure apparatus. In the case of an illumination optical unit for a VUV or EUV projection exposure apparatus, the optical component is preferably arranged in an evacuated chamber. During the operation of the projection exposure apparatus, the chamber can be evacuated in particular to a pressure of less than 50 Pa, in particular less than 20 Pa, in particular less than 10 Pa, in particular less than 5 Pa. In this case, the pressure indicates in particular the partial pressure of hydrogen in the chamber.

High-energy photons from the radiation source, in particular EUV photons, can lead to the generation of a plasma, in particular a hydrogen plasma. Other ionization mechanisms, for example the external photoelectric effect, in particular also VUV photons, are likewise possible. The radiation-induced free charge carriers can accumulate on the mirror and lead to a mechanical disturbance thereof.

One aspect of the disclosure provides for the at least one mechanism for reducing a radiation-induced influence on the positioning of the at least one optical device to include a control device for the targeted application of an electrical bias potential to the at least one optical device. In other words, the electrical bias potential is applied to the optical device, such that the optical device is at the potential.

This makes it possible to reduce, in particular to minimize, in particular to eliminate, the radiation transfer, in particular the plasma-induced charge transfer, to the optical device. The bias potential can be chosen in particular in such a way that the current flowing away via the mirror is reduced, in particular minimized, in particular eliminated.

The bias potential can be fixedly predefined. It can also be controllable, in particular dynamically controllable, in particular controllable by closed-loop control.

Alternatively or additionally, a control device for the targeted application of a bias voltage to an actuator device can also be provided as mechanism for reducing a radiation-induced influence on the positioning of the at least one optical device.

According to the disclosure it has been recognized that, by applying a bias voltage to the actuator device, the effective elasticity constant of the optical device is modifiable.

In accordance with one aspect of the disclosure, the control device includes a look-up table for determining the bias potential to be applied to the at least one optical device. The complexity of the control device is simplified as a result. Determining the bias potential with the aid of a look-up table makes possible, in particular, an uncomplicated, cost-effective control. It is also possible to provide the control device with a plurality of look-up tables for different operating modes of the projection exposure apparatus. By way of example, in each case a dedicated look-up table can be provided for different radiation sources. The look-up tables can each have different values for the bias potential to be applied for different operating modes of the radiation source. In this case, they can have, in particular, different pulse frequencies, pulse durations and intensities of the radiation source and also different states of the evacuatable chamber, in particular the pressure thereof, in particular the partial pressures for different gases and also the gas composition in the chamber.

The look-up tables can be determined offline. They can be determined experimentally, in particular. They can also be determined with the aid of a model. In one particular advantageous embodiment, provision can also be made for designing the control device in such a way that the look-up tables can be calibrated during the operation of the projection exposure apparatus.

One aspect of the disclosure provides for the control device to include at least one sensor, that is to say to be embodied as a closed-loop control device with at least one sensor.

In particular, a current flowing away through the mirror can be detected via the sensor. With the aid of the sensor, it is possible, in particular, to make the determination of the bias potential dynamically controllable by closed-loop control. The stability of the device is improved further as a result. It is possible, in particular, to monitor the effect of the bias potential with the aid of the sensor and to calibrate the exact value of the bias potential to be applied during the operation of the projection exposure apparatus.

In accordance with one aspect of the disclosure, provision can be made for the at least one mechanism for reducing a radiation-induced influence on the positioning of the at least one optical device to include at least one control device for applying a compensation potential to the at least one optical device and/or the at least one actuator device. The compensation potential can be applied in particular as part of the bias potential directly to the optical device. This enables, in particular, a particularly direct, unfiltered dynamic compensation of radiation-induced influences. As an alternative or in addition thereto, a compensation potential can also be applied to the actuator device. In this case, the electrical properties of the actuator device and also the actuation characteristic thereof should be taken into consideration when determining the compensation potential.

The compensation potential applied directly to the optical device can be, in particular, a time-dependent portion of the bias potential. In accordance with one aspect of the disclosure, the control device, for acting on the optical device and/or the actuator device, includes a sensor device for detecting a radiation-induced charge offset in the optical device to be acted on. If the time constant of the electrical equivalent circuit of the optical device is significantly shorter than the characteristic time scale of the external electrical disturbances of the optical device, the current flowing away from the optical device is substantially resistive, that is to say in phase with the external disturbances. In this case, the charge offset can be compensated for by the application of a corresponding compensation potential. Preferably, the sensor device for detecting the charge offset has a sampling frequency (sampling rate) that is greater than the pulse frequency of the radiation source. The sampling frequency of the sensor device is in particular at least double the magnitude, in particular at least five times the magnitude, in particular at least ten times the magnitude, of the pulse frequency of the radiation source. The compensation potential can thus be generated with substantially negligible delay and be applied to the optical device.

In accordance with a further aspect of the disclosure, the at least one mechanism for reducing the radiation-induced influence on the positioning of the at least one optical device includes at least one shielding element.

The shielding element is preferably arranged in the beam path upstream of the optical device. In other words, it is arranged in the beam path in the region between the radiation source and the optical device. It serves for electrostatic shielding, in particular. It also leads to electrodynamic shielding. The shielding element includes in particular a grating and/or a mask, in particular a metal sheet.

The shielding element is preferably composed of an electrically conductive material. It can be composed of metal, in particular. In the region of the optical device, the shielding element is substantially radiation-transmissive. It is designed and/or arranged in particular in such a way that it leads to at most negligible shading of the optical device. It is designed in particular as a grating. In this case, the grating dimensions are adapted to the dimensions of the optical devices. The grating webs are adapted in particular to the distances between adjacent micromirrors. They have in particular a thickness which is smaller than the distance between adjacent micromirrors. The thickness of the grating webs is in particular at most half the magnitude, in particular at most 0.2 times the magnitude, in particular at most 0.1 times the magnitude, of the distance between adjacent mirrors of the optical component.

The distance between adjacent grating webs corresponds in particular to the dimensions of the mirrors, wherein the distance between adjacent mirrors should be taken into account, of course.

The grating can be a simple grating having exclusively parallel grating bars. A grating having crossed grating bars, in particular grating bars oriented perpendicularly to one another, can also be involved. The grating structure can be adapted in particular to the arrangement of the micromirrors. It is possible, in particular, for the grating structure to correspond precisely to the arrangement of the interspaces between the individual micromirrors.

In the region which lies in a projection in the direction of the optical axis outside the totality of the optical devices of the optical component, the shielding element can be embodied in a planar fashion, that is to say in a closed fashion. It can be embodied in particular as a mask, in particular as a shielding plate, in the region.

In accordance with one aspect of the disclosure, the at least one shielding element includes a control device for the targeted application of an electrical potential to the at least one shielding element. The shielding via the shielding element, in particular via the grating can be improved further as a result.

The shielding element is arranged in particular at a distance from the optical device which is at least equal to a side length or a diameter of the optical device.

The shielding element is preferably electrically insulated from the remainder of the optical component, in particular from the optical device and/or the actuator device.

The disclosure seeks to improve a method for positioning an optical device.

The disclosure provides a method for positioning the at least one optical device, which includes providing an optical component disclosed herein, and applying an electrical potential to the at least one optical device and/or the at least one actuator device and/or at least one shield element. The method is, in particular, a method for reducing the radiation-induced influence on the positioning of a displaceable optical device. The method according to the disclosure improves in particular the stability and the precision of the positioning of the displaceable optical device.

Advantages are evident from the above description of the optical component. In order to reduce the radiation-induced influence on the positioning of the displaceable optical device, provision is made in particular for applying an electrical bias or compensation potential to the at least one optical device and/or the at least one actuator device and/or the at least one shielding element. This can be a constant potential or a time-dependent potential. The potential can be adapted in particular to the dynamic range of the radiation source, in particular to the pulse frequency thereof.

Further aspects of the disclosure are to improve an illumination optical unit and an illumination system for a projection exposure apparatus and a projection exposure apparatus including an illumination optical unit of this type.

Aspects of the disclosure are achieved via an illumination optical unit for a projection exposure apparatus which includes at least one optical component disclosed herein, an illumination system including such an illumination optical unit and a radiation source, a projection exposure apparatus include such an illumination optical unit, and a method of making a micro- or nanostructured component using such a projection exposure apparatus.

The advantages are evident from the above-described advantages of the optical component.

The advantages of the optical component according to the disclosure are manifested particularly well with the use of an illumination system including an EUV radiation source having a generated used radiation in the range of 5 nm to 30 nm or a VUV radiation source having a used radiation in the range of less than 200 nm.

A further aspect of the disclosure is to improve a method for producing a micro- or nanostructured component.

The disclosure provides a method for producing a micro- or nanostructured component, which includes: providing a wafer, to which a layer composed of a light-sensitive material is at least partly applied; providing a reticle having structures to be imaged; providing a projection exposure apparatus as disclosed herein; and projecting at least one part of the reticle onto a region of the layer of the wafer with the aid of the projection exposure apparatus.

The advantages are evident from those described above.

### BRIEF DESCRIPTION OF THE DRAWINGS

Further details and advantages of the disclosure will become apparent from the description of exemplary embodiments with reference to the drawings, in which:

FIG. 1 schematically shows a microlithographic projection exposure apparatus with—illustrated in meridional section—an illumination optical unit and a projection optical unit;

FIG. 2 schematically shows two mutually adjacent individual mirrors of an embodiment of one of the facet mirrors of the illumination optical unit according to FIG. 1 in a sectional side view, wherein the individual mirror illustrated on the left in FIG. 2 is illustrated in an untilted neutral position and the individual mirror illustrated on the right in FIG. 2 is illustrated in a position tilted by the actuator;

FIG. 3 shows a section according to line III-III in FIG. 2, wherein the line II-II indicates the direction of the section in FIG. 2,

FIG. 4 shows a schematic illustration of the individual mirrors in accordance with FIG. 2, in which illustration the contact structures are highlighted,

FIG. 5 shows a schematic illustration of the individual mirrors in accordance with FIG. 2, which illustration schematically illustrates the control device for applying an electrical bias potential to the individual mirrors,

FIG. 6 shows a schematic illustration of the method for optimizing the bias potentials to be applied,

FIG. 7 shows a schematic illustration of the method for the offline determination of the dynamic bias potentials to be applied,

FIG. 8 shows a schematic illustration of the method for applying the bias potentials,

FIG. 9 shows a schematic illustration of the method for a real-time adaptation of the bias potentials,

FIG. 10 shows an illustration of the facet mirror with a shielding element, and

FIG. 11 shows a plan view of the facet mirror in accordance with FIG. 10.

### DETAILED DESCRIPTION

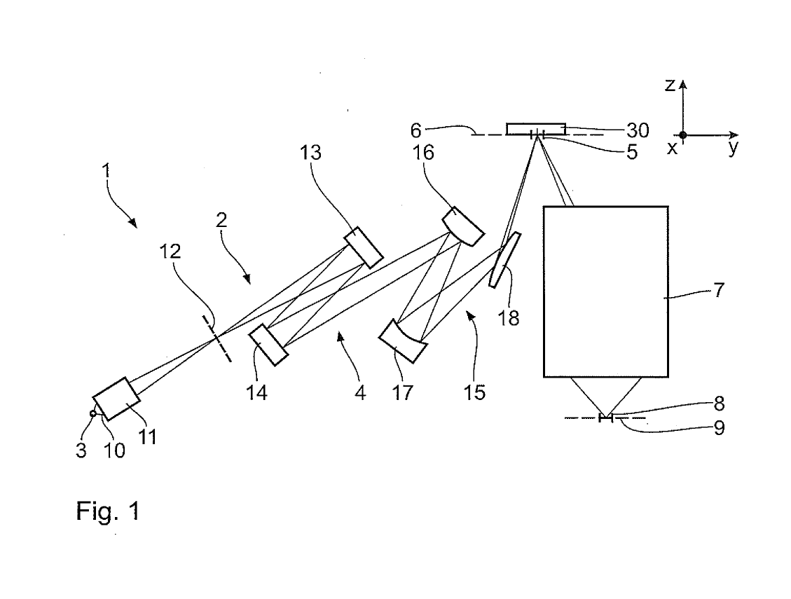

FIG. 1 schematically shows a microlithographic projection exposure apparatus 1 in a meridional section. An illumination system 2 of the projection exposure apparatus 1 has, besides a radiation source 3, an illumination optical unit 4 for exposing an object field 5 in an object plane 6. The object field 5 can be fashioned rectangularly or arcuately with an x/y aspect ratio of 13/1, for example. In this case, a reflective reticle (not illustrated in FIG. 1) arranged in the object field 5 is exposed, the reticle bearing a structure to be projected by the projection exposure apparatus 1 for the production of micro- or nanostructured semiconductor components. A projection optical unit 7 serves for imaging the object field 5 into an image field 8 in an image plane 9. The structure on the reticle is imaged onto a light-sensitive layer of a wafer arranged in the region of the image field 8 in the image plane 9, the wafer not being illustrated in the drawing.

The reticle, which is held by a reticle holder (not illustrated), and the wafer, which is held by a wafer holder (not illustrated), are scanned synchronously in the y-direction during the operation of the projection exposure apparatus 1. Depending on the imaging scale of the projection optical unit 7, it is also possible for the reticle to be scanned in the opposite direction relative to the wafer.

The radiation source 3 is an EUV radiation source having an emitted used radiation in the range of between 5 nm and 30 nm. This can involve a plasma source, for example a GDPP source (gas discharge produced plasma) or an LPP source (laser produced plasma). Other EUV radiation sources, for example those based on a synchrotron or on a free electron laser (FEL), are also possible.

A VUV radiation source, in particular for generating radiation having a wavelength of less than 200 nm, can also be involved.

EUV radiation 10 emerging from the radiation source 3 is concentrated by a collector 11. A corresponding collector is known for example from EP 1 225 481 A. Downstream of the collector 11, the EUV radiation 10 propagates through an intermediate focal plane 12 before it impinges on a field facet mirror 13. The field facet mirror 13 is arranged in a plane of the illumination optical unit 4 which is optically conjugate with respect to the object plane 6.

The EUV radiation 10 is hereinafter also designated as used radiation, illumination light or as imaging light. The used radiation can also be VUV radiation, in particular having a wavelength of less than 200 nm.

Downstream of the field facet mirror 13, the EUV radiation 10 is reflected by a pupil facet mirror 14. The pupil facet mirror 14 lies either in the entrance pupil plane of the illumination optical unit 7 or in a plane that is optically conjugate with respect thereto. The field facet mirror 13 and the pupil facet mirror 14 are constructed from a multiplicity of individual mirrors, which will be described in even greater detail below. In this case, the subdivision of the field facet mirror 13 into individual mirrors can be such that each of the field facets, which by themselves illuminate the entire object field 5, is represented by exactly one of the individual mirrors. Alternatively, it is possible for at least some or all of the field facets to be constructed by a plurality of such individual mirrors. The same correspondingly applies to the configuration of the pupil facets of the pupil facet mirror 14 respectively assigned to the field facets, which pupil facets can in each case be formed by a single individual mirror or by a plurality of such individual mirrors.

The EUV radiation 10 impinges on the two facet mirrors 13, 14 at an angle of incidence which is less than or equal to 25°. Therefore, the EUV radiation 10 is applied to the two facet mirrors in the range of normal incidence operation. Application with grazing incidence is also possible. The pupil facet mirror 14 is arranged in a plane of the illumination optical unit 4 which constitutes a pupil plane of the projection optical unit 7 or is optically conjugate with respect to a pupil plane of the projection optical unit 7. With the aid of the pupil facet mirror 14 and an imaging optical assembly in the form of a transfer optical unit 15 having mirrors 16, 17 and 18 designated in the order of the beam path for the EUV radiation 10, the field facets of the field facet mirror 13 are imaged into the object field 5 in a manner superimposed on one another. The last mirror 18 of the transfer optical unit 15 is a mirror for grazing incidence (“grazing incidence mirror”). The transfer optical unit 15 together with the pupil facet mirror 14 is also designated as subsequent optical unit for transferring the EUV radiation 10 from the field facet mirror 13 toward the object field 5. The illumination light 10 is guided from the radiation source 3 toward the object field 5 via a plurality of illumination channels. Each of the illumination channels is assigned a field facet of the field facet mirror 13 and a pupil facet of the pupil facet mirror 14 disposed downstream thereof. The individual mirrors of the field facet mirror 13 and of the pupil facet mirror 14 can be tiltable by an actuator system, with the result that a change in the assignment of the pupil facets to the field facets and accordingly a changed configuration of the illumination channels can be achieved. This results in different illumination settings which differ in the distribution of the illumination angles of the illumination light 10 over the object field 5.

In order to facilitate the explanation of positional relationships, inter alia a global Cartesian xyz coordinate system is used hereinafter. The x-axis runs perpendicularly to the plane of the drawing toward the observer in FIG. 1. The y-axis runs toward the right in FIG. 1. The z-axis runs upward in FIG. 1.

Different illumination settings can be achieved via a corresponding tilting of the individual mirrors of the field facet mirror 13 and a corresponding change in the assignment of the individual mirrors of the field facet mirror 13 to the individual mirrors of the pupil facet mirror 14. Depending on the tilting of the individual mirrors of the field facet mirror 13, the individual mirrors of the pupil facet mirror 14 that are newly assigned to the individual mirrors are tracked if desired by tilting such that an imaging of the field facets of the field facet mirror 13 into the object field 5 is once again ensured.

The field facet mirror 13 in the form of a multi- or micro-mirror array (MMA) forms an optical assembly for guiding the used radiation 10, that is to say the EUV radiation beam. The field facet mirror 13 is embodied as a microelectromechanical system (MEMS). It has a multiplicity of individual mirrors 27 arranged in matrix-like fashion in rows and columns in an array. The individual mirrors 27 are designed to be tiltable by an actuator system, as will also be explained below. Overall, the field facet mirror 13 has approximately 100 000 of the individual mirrors 27. Depending on the size of the individual mirrors 27, the field facet mirror 13 can also have for example 1000, 5000, 7000 or else hundreds of thousands of individual mirrors 27, in particular at least 100 000 individual mirrors 27, in particular at least 300 000 individual mirrors 27, in particular at least 500 000 individual mirrors 27.

A spectral filter can be arranged upstream of the field facet mirror 13, that is to say between the radiation source 3 and the field facet mirror 13, the spectral filter separating the used radiation 10 from other wavelength components—not usable for the projection exposure—of the emission of the radiation source 3. The spectral filter is not illustrated.

Used radiation 10 having a power of 840 W and a power density of 6.5 kW/m² is applied to the field facet mirror 13. Generally, other powers and power densities are also possible. The power density is at least 500 W/m², in particular at least 1 kW/m², in particular at least 5 kW/m², in particular at least 10 kW/m², in particular at least 60 kW/m².

The entire individual-mirror array of the facet mirror 13 has a diameter of 500 mm and is designed in a manner closely packed with the individual mirrors 27. The individual mirrors 27 represent, insofar as a field facet is realized by in each case exactly one mirror element, apart from a scaling factor, the form of the object field 5. The facet mirror 13 can be formed from 500 individual mirrors 27 respectively representing a field facet and having a dimension of approximately 5 mm in the y-direction and 100 mm in the x-direction. As an alternative to the realization of each field facet by exactly one individual mirror 27, each of the field facets can be approximated by groups of smaller individual mirrors 27. A field facet having dimensions of 5 mm in the y-direction and of 100 mm in the x-direction can be constructed e.g. via a 1×20 array of individual mirrors 27 having the dimensions of 5 mm×5 mm through to a 10×200 array of individual mirrors 27 having the dimensions of 0.5 mm×0.5 mm. The area coverage of the complete field facet array by the individual mirrors 27 can be at least 70%, in particular at least 80%, in particular at least 90%.

The used light 10 is reflected from the individual mirrors 27 of the facet mirror 13 toward the pupil facet mirror 14. The pupil facet mirror 14 has approximately 2000 static pupil facets. The latter are arranged in a plurality of concentric rings alongside one another, such that the pupil facets of the innermost ring are configured in sector-shaped fashion and the pupil facets of the rings directly adjacent thereto are configured in ring-sector-shaped fashion. In a quadrant of the pupil facet mirror 14, pupil facets can be present alongside one another in each of the rings 12. The pupil facets can be embodied in each case in a simply connected fashion. An arrangement of the pupil facets that deviates therefrom is likewise possible. They can also be formed from a multiplicity of individual mirrors 27.

The used light 10 is reflected from the pupil facets toward a reflective reticle 30 arranged in the object plane 6. The projection optical unit 7 then follows, as explained above. The individual mirrors 27 of the field facet mirror 13 and of the pupil facet mirror 14 bear multilayer coatings for optimizing their reflectivity at the wavelength of the used radiation 10. The temperature of the multilayer coatings should not exceed 425 K during the operation of the projection exposure apparatus 1.

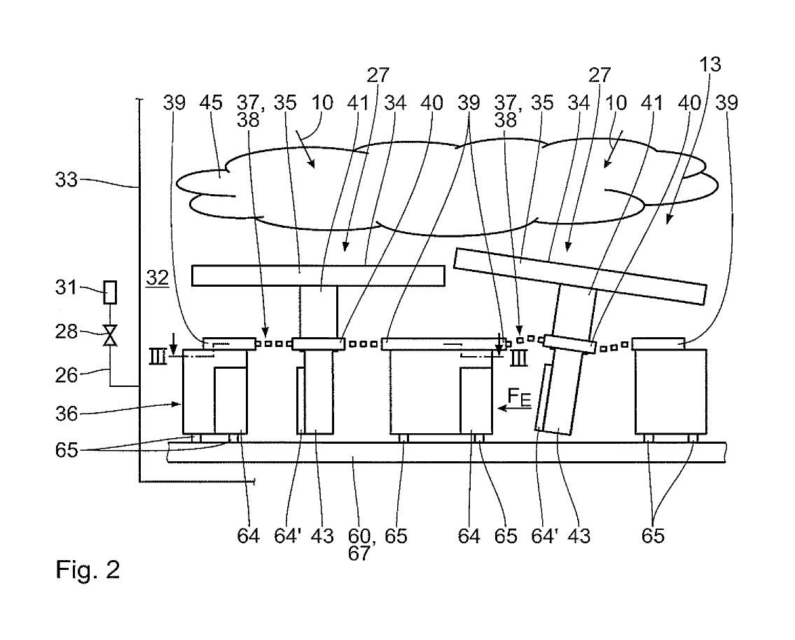

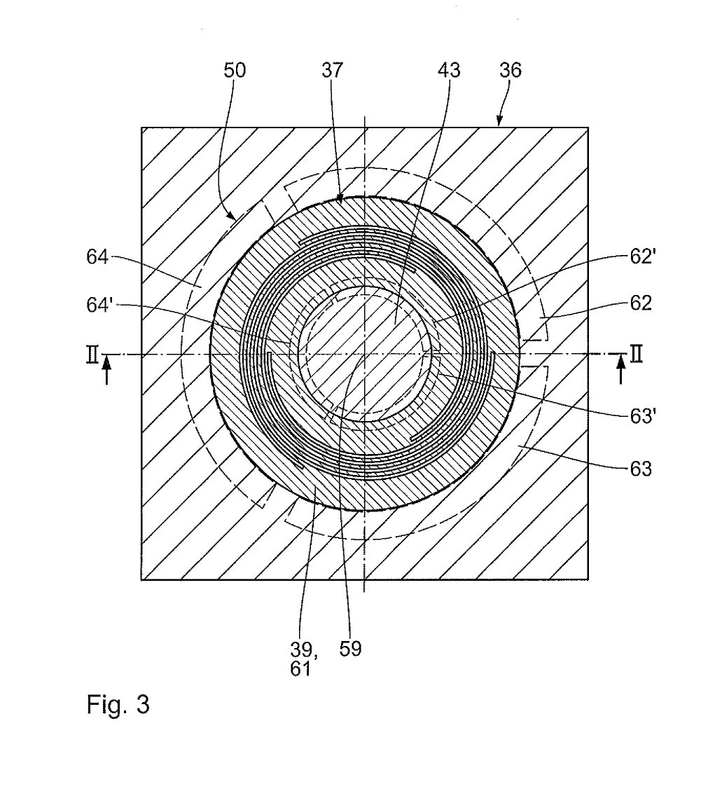

The construction of the individual mirrors is explained by way of example below with reference to FIGS. 2 and 3. For further details of the construction of the individual mirrors 27 and the displaceability thereof, reference should be made to WO 2010/049 076 A1. The document is incorporated within its full scope in the present application as part thereof.

The individual mirrors 27 of the illumination optical unit 4 are accommodated in an evacuatable chamber 32, of which a boundary wall 33 is indicated in FIG. 2. The chamber 32 communicates with a vacuum pump 31 via a fluid line 26, in which a shutoff valve 28 is accommodated.

The operating pressure in the evacuatable chamber 32 is a few Pa (particular pressure H₂). The partial pressure of hydrogen is in particular at most 50 Pa, in particular at most 20 Pa, in particular at most 10 Pa, in particular at most 5 Pa. All other partial pressures are distinctly below 1×10⁻⁷ mbar. The chamber 32 can be evacuated in particular to high vacuum or ultra-high vacuum.

The mirror having the plurality of individual mirror 27, together with the evacuatable chamber 32, is part of an optical component for guiding a beam of the EUV radiation 10. The individual mirror 27 can be part of one of the facet mirrors 13, 14.

Each of the individual mirrors 27 can have an impingable reflection surface 34 having dimensions of 0.5 mm×0.5 mm or else of 5 mm×5 mm or greater. The reflection surface 34 is part of a mirror body 35 of the individual mirror 27. The mirror body 35 bears the multilayer coating. The individual mirrors 27 or the reflection surface 34 thereof can also have other dimensions. They are embodied as tiles, in particular, with which a two-dimensional area can be tiled. They are embodied in particular as triangular, quadrilateral, in particular square, or hexagonal. Their side lengths have in particular dimensions of at most 10 mm, in particular at most 5 mm, in particular at most 3 mm, in particular at most 1 mm, in particular at most 0.5 mm, in particular at most 0.3 mm, in particular at most 0.1 mm. In particular, micromirrors can thus be involved. The latter should be understood to mean in particular mirrors having dimensions in the micrometers range.

The reflection surfaces 34 of the individual mirrors 27 complement one another to form a total mirror reflection surface of the field facet mirror 13. Correspondingly, the reflection surfaces 34 can also complement one another to form the total mirror reflection surface of the pupil facet mirror 14.

A carrying structure 36 or a substrate of the individual mirror 27 is mechanically connected to the mirror body 35 via a heat conducting section 37 (cf. FIG. 2). Part of the heat conducting section 37 is a flexure body 38 that permits the mirror body 35 to be tilted relative to the carrying structure 36. The flexure body 38 can be embodied as a flexure that permits the mirror body 35 to be tilted about defined degrees of freedom of tilting, for example about one or about two tilting axes. The flexure body 38 has an outer holding ring 39 fixed to the carrying structure 36. Furthermore, the flexure body 38 has an inner holding body 40 connected to the holding ring 39 in an articulated manner. The holding body is arranged centrally below the reflection surface 34. A spacer 41 is arranged between the central holding body 40 and the mirror body 35.

The carrying structure 36 has cooling channels, through which an active cooling fluid is passed. For further details of the carrying structure 36 and in particular the thermal budget thereof, reference should again be made to WO 2010/049 076 A1. Alternative embodiments of the flexure body 38 are known in particular from WO 2010/049 076 A1.

On that side of the holding body 40 which faces away from the spacer 41, an actuator pin 43, which continues the spacer 41 with a smaller external diameter, is mounted on the holding body.

The carrying structure 36 is configured as a sleeve surrounding the actuator pin 43. The carrying structure 36 can be a silicon wafer, for example, on which is arranged an entire array of individual mirrors 27 of the type of the individual mirror 27 shown in FIG. 2.

The individual mirrors 27 are each displaceable, that is to say positionable, via an actuator device 50 having a plurality of electromagnetically, in particular electrostatically, operating actuators. The actuators can be produced in a batch process as a microelectromechanical system (MEMS). For details, reference should again be made to WO 2010/049 076 A1.

A sum of the areas of the reflection surfaces 34 on the mirror bodies 35 is greater than 0.5 times a total surface area occupied by the total reflection surface area of the field facet mirror 13. In this case, the total surface area is defined as the sum of the areas of the reflection surfaces 34 plus the area occupied by the interspaces between the reflection surfaces 34. A ratio of the sum of the areas of the reflection surfaces of the mirror bodies, on the one hand, in relation to the total surface area is also designated as the integration density. This integration density can also be greater than 0.6, in particular greater than 0.7, in particular greater than 0.8, in particular greater than 0.9.

With the aid of the projection exposure apparatus 1, at least one part of the reticle 30 is imaged onto a region of a light-sensitive layer on the wafer for lithographically producing a micro- and/or nanostructured component, in particular a semiconductor component, e.g. a microchip. Depending on the embodiment of the projection exposure apparatus 1 as a scanner or as a stepper, the reticle 30 and the wafer are moved in a temporally synchronized manner in the y-direction continuously in scanner operation or step by step in stepper operation.

The optical component in accordance with FIG. 2 is preferably operated in high vacuum or ultra-high vacuum. In this case, a plasma 45, in particular a hydrogen plasma, can form in the region upstream of the individual mirrors 27, in particular upstream of the mirror bodies 35 having the reflection surfaces 34. The plasma 45 can be generated in particular by high-energy photons of the used radiation 10. The properties of the plasma 45 are thus dependent in particular on the properties of the radiation source 3, in particular the operating mode thereof, in particular the pulse frequency and/or pulse duration and/or intensity thereof, and the atmosphere in the chamber 32.

Three electrodes 62, 63, 64 are integrated in the sleeve of the carrying structure 36, which electrodes are arranged in a manner electrically insulated from one another and extending over approximately just less than 120° in each case in a circumferential direction around a center 59 of the actuator pin 43. The electrodes 62 to 64 constitute counterelectrodes with respect to the actuator pin 43, which is embodied as an electrode pin. The electrodes 62, 63, 64 are parts of an actuator device 50.

The actuator pin 43 can be embodied as a hollow cylinder. In a further embodiment of the actuator device 50, there can also be two, four or more electrodes instead of the three electrodes 62 to 64. The electrodes 62 to 64 can respectively interact with their matched electrodes 62′ to 64′ on the actuator pin 43.

In FIG. 2 on the right, the individual mirror 27 is shown in a tilted position in which the counterelectrode 64 is connected at a positive potential V+ relative to the negative potential V− of the actuator pin 43. On account of this potential difference V+/V−, a force F_{E} arises, which draws the free end of the actuator pin 43 toward the counterelectrode 64, which leads to a corresponding tilting of the individual mirror 27. In this case, the resilient suspension provides for a compliant and controlled tilting of the individual mirror 27. Moreover, this resilient suspension provides for a high stiffness of the individual mirror 27 in relation to translational movements in the plane of the resilient suspension, which is also designated as high in-plane stiffness. This high stiffness completely or largely suppresses an undesired translational movement of the actuator pin 43, that is to say of the electrode pin, in the direction toward the electrodes 62 to 64. An undesired reduction of a possible tilting angle range of the actuator pin 43 and thus of the mirror body 35 is avoided in this way.

Depending on the choice of the relative potential of the counterelectrodes 62 to 64 with respect to the potential of the associated electrode 62′ to 64′ of the actuator pin 43, the individual mirrors 27 can be tilted by a predefined tilting angle. In this case, not just tilting angles which correspond to an inclination of the actuator pin 43 exactly toward one of the three counterelectrodes 62 to 64, but also, depending on a predefined potential combination of the counterelectrodes 62 to 64, any other tilting angle orientations are possible.

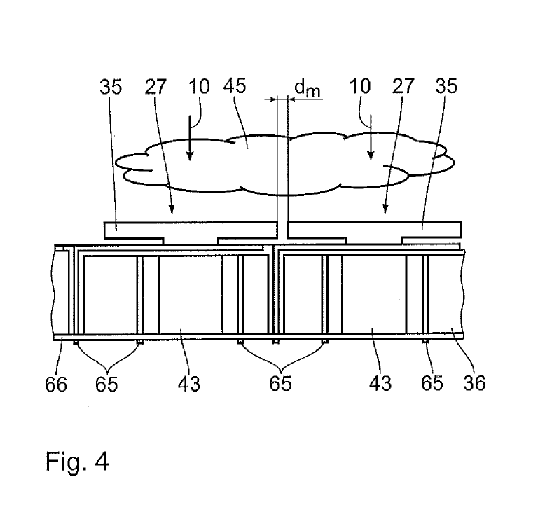

With regard to a method for producing the optical component and the actuator device 50 and the associated electronics for driving the actuator device 50 and the constructional details of the electronics, in particular of the corresponding control device, reference should again be made to WO 2010/049 076 A1. The control device for the actuator device 50 is integrated in particular into one or a plurality of application specific integrated circuits (ASICs) 60, which are merely illustrated schematically in FIG. 2. An exemplary illustration of the contact structures, in particular of the electrical connections 65 for the actuator device 50, in particular the electrodes 62 to 64 and 62′ to 64′, is reproduced in FIG. 4. This also schematically indicates that the contact structures are electrically insulated from the carrying structure 36 by an insulation layer 66.

Further details of the facet mirror 13, 14 embodied as a multi-mirror array (MMA) are described below.

The multi-mirror arrangement (MMA) is produced by a sequence of microelectromechanical structuring steps (MEMS), in particular using lithographic method steps, such as, for example, etching, deposition, bonding or molding. It is produced in particular from a number of individual wafers which are bonded to one another after processing.

The individual mirrors 27 embodied as micromirrors are suspended on microscopic bending structures. The latter can be cut out or etched out from a thin silicon wafer or from a metallic membrane or the like. The bending structures can be embodied in particular two-dimensionally, that is to say in a membrane-like fashion, or in a beam-type or cardan-type fashion.

The actuator is preferably electrostatic or electromechanical. Alternatives thereto are likewise possible, however.

The individual mirrors 27 can be pivoted by at least 80 mrad, in particular at least 100 mrad, in any radial direction.

The number of individual mirrors 27 of the multi-mirror array (MMA) is in the range of 1 to 1 000 000. It can also be more than that, in principle. It can be chosen freely, in principle, depending on the desired properties. The total number of individual mirrors 27 of the facet mirror 13, 14 can be in particular in the millions.

The electrical connections, in particular the circuits, can be produced as follows: the horizontally running electrical connections, that is to say those running in a direction parallel to a wafer surface, can be applied as thin metallic layers to the surface of the individual wafers. A printing or vapor deposition method can be provided for this purpose. The vertical electrical connections, that is to say the connections extending through the wafers, for example the carrying structure 36, can be produced by etching channels and/or opening and filling the same with metal, for example as so-called silicon plated-through holes. An MEMS method can be provided for this purpose, too.

An electronic control device 67 for control, in particular for closed loop control of the actuator device 50, is arranged on the rear side of the optical component, that is to say on the opposite side of the individual mirrors 27 relative to the reflection surface 34 thereof. The control device 67 includes in particular the ASICs 60 already mentioned. The control device 67 is electrically conductively connected via the electrical connections 65 to the electrodes 62 to 64, 62′ to 64′ of each of the individual mirrors 27 or of the actuator device 50. The control device 67 can be embodied in an embedded fashion, in particular as a microscopically embodied integrated circuit (IC) or as a separate, external component. For details of how the electrical connections between the multi-mirror array, in particular between the actuator device 50 and the control device 67, are produced, reference should again be made to WO 2010/049 076 A1.

The optical component is operated in particular in the chamber 32 with reduced pressure. The residual gas in the chamber 32 has a partial pressure of at most 50 Pa, in particular at most 30 Pa, in particular at most 10 Pa, preferably at most 5 Pa, during the operation of the projection exposure apparatus 1, in particular during the operation of the illumination system 2. The gas can be in particular hydrogen, helium or argon. Other gases are also possible, in principle.

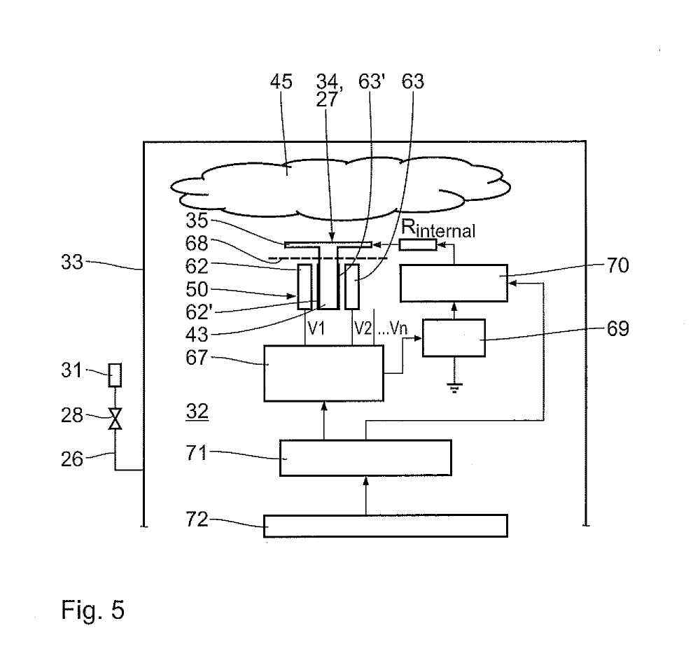

The surfaces of the actuator electrodes 62 to 64, 62′ to 64′ have to be shielded from the electrically charged plasma 45. This is achieved firstly via the mirror bodies 35 arranged between the plasma 45 and the actuator electrodes 62 to 64, 62′ to 64′. Moreover, as is illustrated schematically in FIG. 5, a specific shielding element can be arranged in the region between the mirror bodies 35 and the actuator electrodes 62 to 64, 62′ to 64′. This functionality can likewise be fulfilled by a corresponding embodiment of the holding elements 40. The shielding element 68 can be embodied in a membrane-like, net-like or grating-like fashion. In the case of a net-like or grating-like embodiment, the free width is a maximum of 10 μm. It is also possible to arrange the individual mirrors 27 in such a way that their mutual distance dₘ is less than 10 μm in particular less than 5 μm. In this case, it is possible, in principle, to dispense with the shielding element 68 between the mirror body 35 and the actuator electrodes 62 to 64, 62′ to 64′.

Moreover, precautions can preferably be taken to ensure that no stray light is incident on the surface of the actuator electrodes 62 to 64, 62′ to 64′.

The electronic control device 67 serves in particular for controlling the actuator device 50 having the actuator electrodes 62 to 64′, 62′ to 64′. It can be embodied as an open-loop control device or as a closed-loop control device. In the latter case, it includes a local and/or an external monitoring system, that is to say a sensor device, by which the displacement state, in particular the tilting, of each of the individual mirrors 27 can be monitored.

Moreover, a so-called bias potential V_{Bias} can be applied to the mirror body 35 itself via the control device 67. The supply leads involved for this purpose can be integrated into the carrying structure 36 and into the flexure body 38. The bias potential V_{Bias} can be a constant potential, in particular in the range of −10 V to +10 V. The bias potential V_{Bias} can be set in particular with an accuracy of a few mV or better. A voltage source 69, in particular a controllable voltage source 69, is provided for applying the bias potential V_{Bias} to the mirror bodies 35 of the individual mirrors 27. The voltage source 69 has a time constant, in particular a response time, which is shorter than the reciprocal of the pulse frequency of the radiation source 3.

By applying the potential to the mirror body 35 of the individual mirror 27, it is possible to prevent charges from the plasma 45 from being transferred to the mirror body 35. The charge transfer from the plasma 45 to the mirror body 35 can at least be reduced by the application of the bias potential V_{Bias} to the mirror body. It is possible, in particular, to choose and set the exact value of the bias potential V_{Bias} in such a way that the charge transfer from the plasma 45 to the mirror body 35 of the individual mirror 27 is minimized. The bias potential V_{Bias} can also serve to compensate for the losses of charge from the mirror surface into the surroundings, the losses occurring on account of the photoelectric effect. For this purpose, the bias potential V_{Bias} can be adapted to the operating conditions, in particular to the operating conditions of the radiation source 3, in particular the pulse duration, pulse frequency and intensity thereof, and the atmosphere in the chamber 32. The control device 67 advantageously has a look-up table for this purpose. The method for setting the bias potential V_{Bias} is described in even greater detail below.

In accordance with the embodiment illustrated in FIG. 5, moreover, a sensor device 70 is provided, by which the current flowing away from the plasma 45 through an individual mirror 27 is detectable. The current is dependent on a mirror potential, the V_{Mirror}, generated by a charge transfer from the plasma 45 to the mirror body 35, and the internal electrical resistance between the mirror 27 and the control device 67 or a grounding. The current flow from the plasma 45 through the mirror 27 can be reduced, in particular minimized, in particular eliminated, by suitable setting of the bias voltage V_{Bias} to be applied to the mirror 27 via the control device 67 via the voltage source 69.

The sensor device 70 is preferably designed in such a way that it can detect the current respectively flowing away through the mirror 27 at any mirror potential V_{Mirror} occurring during the operation of the illumination system 2, with a resolution in the nanoamperes range.

In order to simplify the sensor system, it is also possible to provide a plurality of individual mirrors 27 together with a single sensor device 70. In this case, the sensor device 70 can detect either the average value or the sum or an individual value of the current flowing away through the mirrors 27. The sensor device 70 can be connected for example to two, three, four, six, nine or more individual mirrors 27.

The current measurement via the sensor device 70 can be effected in particular with the aid of a voltage drop across a known resistor. The resistor can be integrated in particular into the MMA structure. It can be embodied for example as a resistive film with circuit connections. The resistor can preferably be integrated as near as possible to the coating of the mirror 27, in particular into the coating. For the further processing, the voltage drop can be read out and converted into a current value.

The sensor device 70 can be connected to an electrical interface 71 in a data-transferring manner. For its part, the electrical interface 71 can be connected in a data-transferring manner firstly to the control device 67, and secondly to an external open-loop or closed-loop control device 72. The external control device 72 can include software or hardware components.

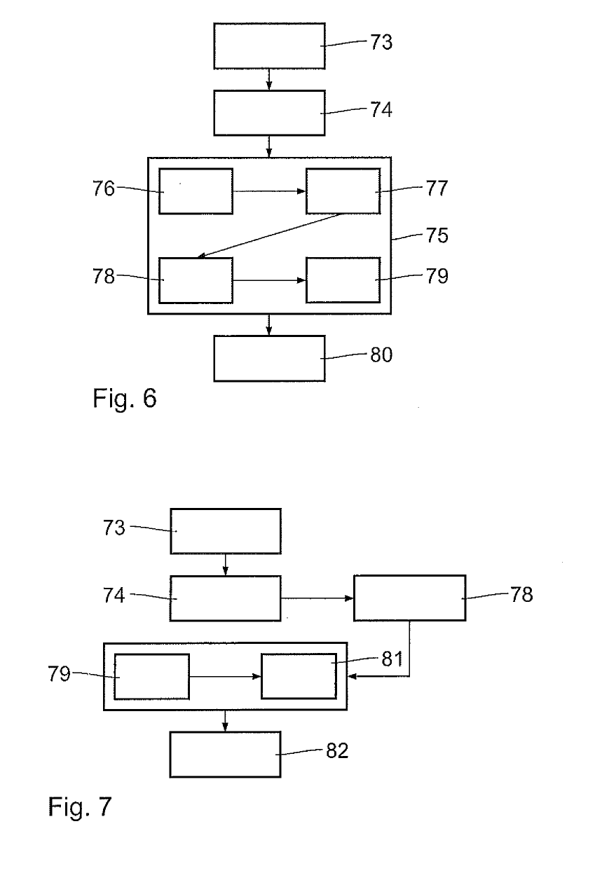

The bias potential V_{Bias} to be applied to the individual mirrors 27 can be determined experimentally. It can be determined in particular offline, in particular before the illumination system 2 is started up. In particular, a look-up table can be created for this purpose. A method for creating such a look-up table is illustrated schematically in FIG. 6. Firstly, in a providing step 73, an illumination system 2 is provided. The illumination system 2 is brought in particular to a state ready for operation. For this purpose, by way of example, the chamber 32 is at least partly evacuated via the vacuum pump 31. In an actuating step 74, the individual mirrors 27 are then brought to the desired position, that is to say positioned, by targeted activation of the actuator device 50. Afterward, in a repeated measuring method 75, firstly, a bias potential V_{Bias} is applied to the individual mirror 27 in an applying step 76, the voltages applied to the actuator electrodes 62 to 64, 62′ to 64′ are adapted in a compensation step 77, the radiation source 3 is activated in an activation step 78, and the current flowing through the individual mirror 27 is measured in a measuring step 79.

The compensation step 77 serves for adapting the actuation voltages in order to reestablish the positioning of the individual mirror 27 as set in the actuating step 74 after the bias voltage V_{Bias} has been applied to the individual mirror in the applying step 76. The application of the bias voltage V_{Bias} to the individual mirror 27 generally involves such a compensation.

The measuring method 75 is repeated for different values of the bias potential V_{Bias}. In principle, the measuring method 75 can also be repeated for different positioning of the individual mirrors 27. Moreover, the measuring method 75 can be repeated for different operating modes of the radiation source 3.

The optimum value, for the respective conditions, of the bias potential V_{Bias}* to be applied to the individual mirror 27 is subsequently determined in an optimization step 80. The optimization step 80 can include an interpolation step.

According to the disclosure it has been found that the optimized bias potentials V_{Bias}* depend for example on the pulse frequency of the radiation source 3. The optimized bias potential V_{Bias}* increases in particular as the frequency of the radiation source 3 increases. The optimized bias potential V_{Bias}* is determined with an accuracy of 10 mV or better. According to the disclosure it has been found that the disturbance caused by the plasma 45, that is to say the radiation-induced influence on the positioning of the individual mirror 27, could be reduced to a tilting of less than 10 μrad.

The above-described calibration method for determining the optimized bias voltage V_{Bias}* can preferably be performed in a fully automated manner. It can be carried out in particular independently at a predefined point in time. It can be carried out in particular at regular intervals. It is possible, in particular, to adapt the optimized bias voltages V_{Bias}* to slow, long-term changes in the radiation source 3, in particular the intensity thereof. Advantageously, the devices used for the calibration method, in particular the electronic devices, are integrated, in particular embedded, into the MMA. The optimized bias potentials V_{Bias}* are in particular in the range of −10 V to +10 V, in particular in the range of −5 V to +5 V.

By applying the bias voltage V_{Bias} to the individual mirrors 27, it is possible to reduce, in particular minimize, in particular eliminate, the interaction between individual mirrors 27 or the actuator device 50 thereof and the surroundings thereof, in particular the plasma 45. In order to address dynamic aspects of the activation of the radiation source 3, preferably a dynamic control, in particular a time-dependent control, can also be provided. This is advantageous in particular if the radiation source 3 is operated in a pulsed manner. A dynamic control of the bias potential V_{Bias} or generally of the mechanism for reducing the radiation-induced influence on the positioning of the individual mirror 27 is advantageous in particular if the electrical properties of the surroundings of the mirrors 27 or of the actuator device 50 are variable, in particular if the properties vary during the operation of the radiation source 3, in particular between two pulses thereof. Dynamic, in particular transient, effects can occur even after the radiation source 3 is switched on or after a relatively long pause. By way of example, time-dependent variations of the plasma 45 can also occur in the interval between the exposure of two wafers. In order to be able to take account of such a time-dependent variation of the plasma 45, provision can be made for measuring the current flowing away via the individual mirror 27 via the sensor device 70 and for determining from the measured current a time-dependent compensation potential V_{Bias}(t)=V_{Comp}, which, when the potential is applied to the individual mirror 27, leads to a reduction, in particular to a minimization, in particular to an elimination, of the current flowing away through the individual mirror 27.

In order that the measured current reproduces as well as possible the dynamic range of the electrical interaction between the individual mirror 27 and the surroundings thereof, the mirror 27 and the sensor device 70 are embodied in such a way that the characteristic time constant of the corresponding equivalent circuit is significantly shorter than the characteristic time of the external electrical disturbances. The time constant of the equivalent circuit of the individual mirror 27 or of the MMA is in particular shorter than 100 msec, in particular shorter than 30 msec, in particular shorter than 10 msec, in particular shorter than 3 msec, in particular shorter than 1 msec, in particular shorter than 0.3 msec, in particular shorter than 0.1 msec, in particular shorter than 10⁻⁵ sec, in particular shorter than 10⁻⁶ sec.

As is illustrated schematically in FIG. 7, the compensation potential V_{Comp} can be determined offline. In this case, in particular each individual mirror 27 can be calibrated in accordance with the flow chart illustrated schematically in FIG. 7. For the purpose of calibration, in particular a providing step 73 is again provided, in which the illumination system 2 is provided and brought to operating conditions. By way of example, the chamber 32 can again be evacuated via the vacuum pump 31. Afterward, provision is again made for displacing the individual mirrors 27 in an actuating step 74, that is to say for positioning the individual mirrors, that is to say for bringing them to the desired position by the activation of the actuator device 50. The radiation source 3 is then activated in an activation step 78. This is followed by the determination of the compensation potential V_{Comp}=V_{Bias}(t). The determination includes a measuring step 79 and a calculating step 81. The temporal profile of the current flowing away via the mirror 27 can be measured in the measuring step 79. From these measurement data, the temporal profile of the desired compensation voltage V_{Comp}=V_{Bias}(t) is determined in the calculating step 81. In a subsequent storage step 82, the function V_{Bias}(t) is stored in free form or in a parameterized fashion.

V_{Comp} can be a periodic function. It can have in particular the same periodicity as the radiation source 3. It can also have higher frequency components. It can also have a transient component, in particular for the interval directly after the radiation source 3 is switched on. It can also have a transition region that takes account of the time duration until the radiation source 3 has reached steady-state conditions. In principle, the function V_{Bias}(t) can also be calculated for the entire duration of the activation of the radiation source 3.

For a correction during the operation of the illumination system, provision is made for applying the compensation voltage V_{Comp}=V_{Bias}(t) to the individual mirror 27. The time dependence of the compensation potential to be applied can be generated with the aid of electronic devices, for example function generators, amplifiers, inverters. The devices can be digital or analog. An external electronic open-loop or closed-open control device or an internal electronic open-loop or closed-loop control device, that is to say one which is integrated into the MMA, can be provided for generating the compensation potential V_{Comp} and/or for applying the latter to the individual mirror 27.

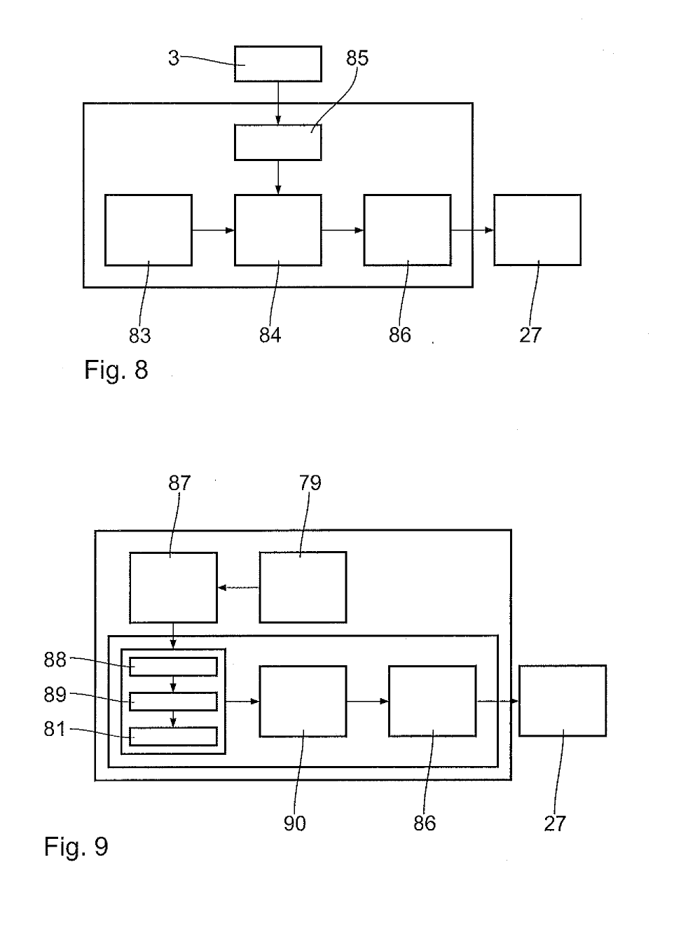

As is illustrated schematically in FIG. 8, the function of the compensation potential V_{Comp}=V_{Bias}(t) is directed from a storage device 83 to a function generator 84. The function generator 84 is synchronized with the radiation source 3 via a synchronization unit. The synchronization unit 85 can be triggered in particular by the radiation source 3. The signal generated by the function generator 84 is forwarded to a voltage amplifier 86. The voltage amplifier 86 is electrically conductively connected to the individual mirror 27. In particular, an electrical connection 65 is provided for this purpose.

In one advantageous embodiment, the control device 67 is fast enough to detect the current through the mirror 27 and to calculate and generate the compensation potential V_{Comp}=V_{Bias}(t) in real time. In this embodiment, the compensation potential is calculated with a clock rate that is greater than the pulse frequency of the radiation source 3. The clock rate for calculating the compensation potential V_{Comp} is in particular at least double the magnitude, in particular at least 5 times the magnitude, in particular at least 10 times the magnitude, in particular at least 20 times the magnitude, in particular at least 50 times the magnitude, of the pulse frequency of the radiation source 3.

Part of the method for a real-time correction is illustrated schematically in FIG. 9. In this case, the current through the mirror 27 is measured by a closed-loop control unit in the measuring step 79. The measured value is then present as an analog signal 87. The analog signal 87 is forwarded to an analog-to-digital converter (ADC) 88 and is then present as a digital real-time sample 89. The compensation potential V_{Comp}=V_{Bias}(t) can be determined from the sample 89 in the calculating step 81. The determination can be effected in particular in a software-based manner. The correction value determined in this way is forwarded to a digital-to-analog converter (DAC) 90. The digital-to-analog converter 90 generates an analog signal V_{Bias}(t) in real time and forwards the signal to the voltage amplifier 86, from where the signal is in turn forwarded to the mirror 27.

In addition thereto, it is possible to adapt the actuator voltage applied to the actuator electrodes 62 to 64, 62′ to 64′. This can be advantageous in particular if the average value of the compensation potential V_{Comp} is not equal to zero. The actuator voltages can be adapted in particular in such a way that the voltage differences between the mirror 27 and the actuator electrodes 62 to 64, 62′ to 64′ are not influenced by the application to the mirror 27, but rather remain constant over time.

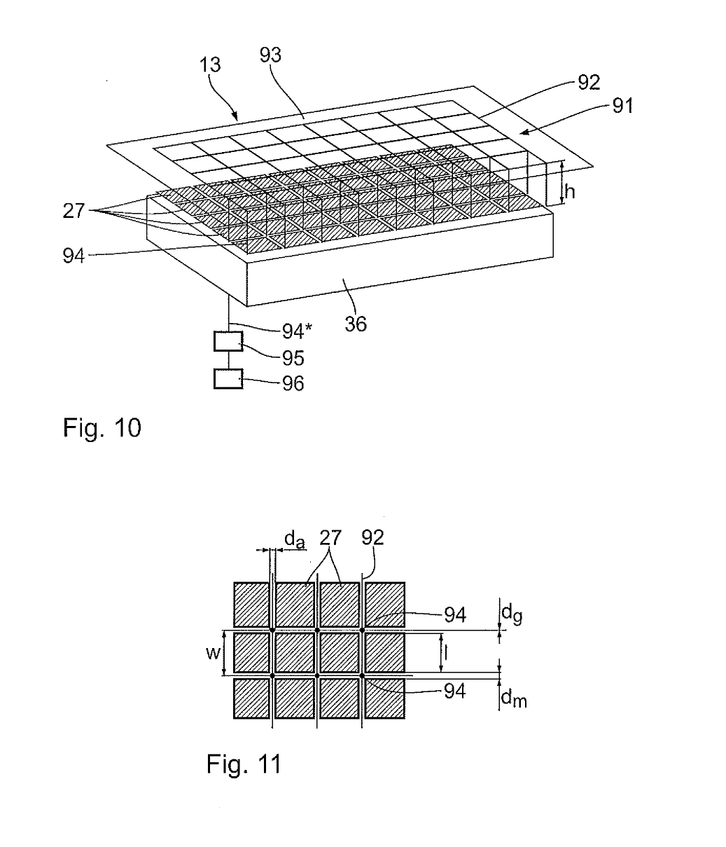

A further embodiment of a mechanism for reducing a radiation-induced influence on the positioning of the individual mirrors 27 is described below with reference to FIGS. 10 and 11.

The basic construction of the multi-mirror array (MMA) including a multiplicity of individual mirrors 27 corresponds to the exemplary embodiment in accordance with FIG. 2, to the description of which reference is hereby made.

In the case of the embodiment in accordance with FIG. 10, the facet mirror 13, which serves as a concrete example of the optical component according to the disclosure, includes a shielding element 91. The shielding element 91 includes a grating 92. The grating 92 can be surrounded marginally by a mask in the form of a metal sheet 93. The grating 92 serves for electrostatically shielding the individual mirrors 27 and the underlying electronics, in particular the ASICs 60.

The grating 92 is composed of an electrically conductive material. The metal sheet 93 surrounding the grating 92 is also composed of an electrically conductive material.

The grating 92 is geometrically adapted to the embodiment of the individual mirrors 27 and the arrangement thereof relative to one another. The individual grating webs form in particular meshes having a width w corresponding to the side length 1 of the individual mirrors 27 increased by the distance dₘ between two adjacent individual mirrors 27 and reduced by the thickness d_{g} of the grating webs.

The grating 92 is arranged at a distance from the individual mirrors 27. It is arranged in particular in the region between the radiation source 3, in particular between the plasma 45, and the individual mirrors 27. It is arranged at a distance h upstream of the individual mirrors 27. In this case, the following holds true: h≧1+dₘ. The grating 92 is arranged relative to the individual mirrors 27 in particular in such a way that its image in the case of a normal projection in the direction of the optical axis on the mirrors 13 is incident in the region between the individual mirrors 27 (see FIG. 11). The thickness d_{g} of the grating webs is in particular less than the distance dₘ between two adjacent individual mirrors 27. The following holds true, in particular: d_{g}≦0.5 dₘ, in particular d_{g}≦0.3 dₘ, in particular d_{g}≦0.2 dₘ, in particular d_{g}≦0.1 dₘ, in particular d_{g}≦0.05 dₘ, in particular d_{g}≦0.03 dₘ, in particular d_{g}≦0.02 dₘ, in particular d_{g}≦0.01 dₘ.

The grating 92 is held via spacers 94 relative to the multi-mirror array (MMA) having the individual mirrors 27. The spacers 94 have a diameter dₐ that is less than the distance dₘ between two adjacent individual mirrors 27. The following holds true, in particular: dₐ≦0.5 dₘ.

The spacers 94 are led through the carrying structure 36. They are led through the carrying structure 36 in particular in through openings. The spacers 94 are electrically insulated in particular from the rest of the carrying structure 36.

The spacers 94 are fitted to the carrying structure 36 in the region between the individual mirrors 27. They are designed and arranged in such a way that they do not influence the displacement, in particular the tilting, of the individual mirrors 27.

The grating 92 is designed in particular in such a way that it does not lead to any shading of the used radiation 10 from the radiation source 3 upon the impingement thereof on the individual mirrors 27.

Moreover, the grating 92 is designed in particular in such a way that diffraction effects thereof on the used radiation 10 are negligible.

At least one of the spacers 94 is embodied as a contact pin 94*. It is composed of an electrically conductive material. The contact pin 94* is electrically conductively connected to a voltage source 95. For its part, the voltage source 95 is controllable via a control device 96.

Via the contact pin 94*, an electrical shielding potential V_{Grating} can be applied to the grating 92. The value of the shielding potential applied to the grating 92 is controllable via the control device 96. It is in the range of −100 V to +100 V, in particular. It is preferably relatively low, that is to say more negative than −10 V.

In order to ensure good results, the following values of the shielding voltage are preferred: a shielding voltage of more negative than −10 V for individual mirrors 27 having a side length 1 of 600 μm given a thickness d_{g} of 20 μm and a distance dₘ of less than 100 μm. A shielding voltage of more negative than −30 V for individual mirrors 27 having a side length 1 of 1 mm given a thickness d_{g} of 20 μm and a distance dₘ of less than 100 μm. For individual mirrors 27 having a side length 1 of less than 1 mm and a grating 92 with d_{g} less than 100 μm, negative potentials of up to −100 V have brought about effective shielding.

The shielding potential V_{Grating} to be applied to the grating 92 can be defined before the operation of the illumination system 2. It can also be determined experimentally. It can be determined and set in particular during the operation of the illumination system 2.

With the aid of the shielding element 91 it is possible to prevent free electrons or ions from the plasma 45, which can lead to a disturbance of the positioning of the individual mirrors 27, from being able to pass to the individual mirrors 27 and/or the actuator device 50.

While in FIG. 10 the grating 92 is embodied as a two-dimensional grating having a mesh structure, it is also possible for the grating 92 to be embodied as a one-dimensional grating in which all the grating webs run parallel to one another.

While the grating 92 in the embodiment in accordance with FIG. 10 is connected to the carrying structure 36, it can also be embodied as a separate device, independently of the multi-mirror array. It can be arranged in particular as a separate device in an adjustable manner in the beam path upstream of the mirror 13.

A further mechanism for reducing a radiation-induced influence on the positioning of the individual mirrors 27 consists in applying a bias voltage to the actuator device 50, in particular the actuator electrodes 62 to 64, 62′ to 64′.

Preferably, in each case two, three or more of the actuator electrodes 62 to 64, 62′ to 64′ are arranged and/or connected to the control device 67 in such a way that they can be operated differentially. The bias voltage is correspondingly applied to at least two of the actuator electrodes 62 to 64, 62′ to 64′ in such a way that the effects of the bias voltage on the positioning of the individual mirrors 27 in each case mutually compensate for one another.

According to the disclosure it has been recognized that, by applying the bias voltage, it is possible to reduce the effective elasticity constant of the individual mirrors 27 in the sense of an excitable mechanical system, in particular in the sense of an excitable oscillator. Likewise, by applying a bias voltage, it is possible to reduce the resonant frequency of the individual mirrors 27. In other words, the application of the bias voltage leads to an improved damping of the individual mirrors 27.

The applied bias voltage can be constant, in particular. Its amplitude is in particular at least equal to the maximum actuation voltage provided for pivoting the individual mirrors 27.

For the purpose of applying the bias voltage to the actuator electrodes 62 to 64, 62′ to 64′, the control device 67 can have a separate voltage source. This can be a DC voltage source.

The different mechanism for reducing a radiation-induced influence on the positioning of the individual mirrors 27 can also be combined with one another.

What is claimed is:

1. An optical component, comprising:
an optical device;
an actuator device configured to displace the optical device; and
a mechanism configured to reduce a radiation-induced influence on a position of the optical device;
wherein the mechanism is configured to be dynamically controlled.

2. The optical component of claim 1, wherein the mechanism is configured to reduce a dynamic disturbance of the position of the optical device.

3. The optical component of claim 1, wherein the mechanism comprises a control device configured to apply, in a targeted manner, an electrical bias potential to the optical device.

4. The optical component of claim 3, wherein the control device comprises a look-up table to determine the bias potential to be applied to the optical device.

5. The optical component of claim 3, wherein the control device comprises a closed-loop control device comprising a sensor.

6. The optical component of claim 3, wherein the control device is configured to apply, in a targeted manner, an electrical bias to the actuator device.

7. The optical component of claim 1, wherein the control device is configured to apply, in a targeted manner, an electrical bias to the actuator device.

8. The optical component of claim 7, wherein the control device comprises a closed-loop control device comprising a sensor.

9. The optical component of claim 1, wherein the mechanism comprises a shielding element.

10. The optical component of claim 9, wherein the shielding element comprises at least one member selected from the group consisting of a grating and a mask.

11. The optical component of claim 9, wherein the shielding element comprises a control device configured to apply, in a targeted manner, an electrical potential to the shielding element.

12. A method of positioning an optical device, the method comprising:
providing the optical component of claim 1; and
applying a time-dependent electrical potential to at least one member selected from the group consisting of the optical device and the actuator device.

13. An optical unit, comprising:
the optical component of claim 1,
wherein the optical unit is a microlithgraphic illumination optical unit.

14. A system comprising:
a radiation source; and
a microlithographic illumination optical unit comprising the optical unit of claim 1.

15. An apparatus, comprising:
a microlithographic illumination optical unit comprising the optical unit of claim 1,
wherein the apparatus is a microlithographic projection exposure apparatus.

16. A method of using a projection exposure apparatus, the method comprising:
using the projection exposure apparatus to project at least a portion of a reticle onto a region of light-sensitive material,
wherein the projection exposure apparatus comprises an illumination optical unit comprising the optical unit of claim 1.

17. An optical component, comprising:
an optical device;
an actuator device configured to displace the optical device; and
a mechanism configured to reduce a dynamic disturbance of a position of the optical device;
wherein the mechanism is configured to be dynamically controlled.

18. A method of positioning an optical device, the method comprising:
providing the optical component of claim 17; and
applying a time-dependent electrical potential to at least one member selected from the group consisting of the optical device and the actuator device.

19. An optical unit, comprising:
the optical component of claim 17,
wherein the optical unit is a microlithgraphic illumination optical unit.

20. A system comprising:
a radiation source; and
a microlithographic illumination optical unit comprising the optical unit of claim 17.

21. An apparatus, comprising:
a microlithographic illumination optical unit comprising the optical unit of claim 17,
wherein the apparatus is a microlithographic projection exposure apparatus.

22. A method of using a projection exposure apparatus, the method comprising:
using the projection exposure apparatus to project at least a portion of a reticle onto a region of light-sensitive material,
wherein the projection exposure apparatus comprises an illumination optical unit comprising the optical unit of claim 17.
